(19) United States
(12) Patent Application Publication
(10) Pub. No.: US 2022/0210914 A1
(43) Pub. Date: Jun. 30, 2022

(54) COPPER CLAD LAMINATE AND PRINTED-CIRCUIT BOARD

(71) Applicant: Shengyi Technology Co., Ltd., Guangdong (CN)

(72) Inventors: Guangbing CHEN, Guangdong (CN); Xianping ZENG, Guangdong (CN); Yongjing XU, Guangdong (CN); Yongming ZHU, Guangdong (CN)

(21) Appl. No.: 17/605,820

(22) PCT Filed: Jan. 14, 2020
(86) PCT No.: PCT/CN2020/071878

§ 371 Date: Oct. 22, 2021

(30) Foreign Application Priority Data
Apr. 24, 2019 (CN) 201910337537.X

(51) Int. Cl. H05K 1/03; H05K 1/09; B32B 5/02; B32B 5/26; B32B 15/14; B32B 15/20; C08L 9/00; C08L 9/06; C08L 51/08

(52) U.S. Cl. CPC H05K 1/0373; C08L 2205/03; B32B 5/02; B32B 5/26; B32B 15/14; B32B 15/20; C08L 9/00; C08L 9/06; C08L 51/08; H05K 2201/0355; B32B 2307/204; B32B 2307/538; B32B 2307/3065; B32B 2457/08; B32B 2260/021; B32B 2260/048; B32B 2262/101; C08L 2201/02; C08L 2203/20; C08L 2205/025; H05K 1/09

(57) ABSTRACT

A copper clad laminate and a printed-circuit board. The copper clad laminate comprises a dielectric substrate layer and a copper foil layer. The copper foil layer is located on at least one surface of the dielectric substrate layer, wherein the copper foil layer comprises an iron element in a weight content of less than 10 ppm, a nickel element in a weight content of less than 10 ppm, a cobalt element in a weight content of less than 10 ppm, and a molybdenum element in a weight content of 10 ppm. The copper clad laminate has a passive intermodulation PIM of less than −158 dBc (700 MHz/2600 MHz).

### TECHNICAL FIELD

The present disclosure belongs to the technical field of electronic materials, and relates to a copper clad laminate and a printed circuit board.

### BACKGROUND

With the development of electronic information technology, digital circuits have gradually entered the stage of high-speed information processing and high-frequency signal transmission. In order to process ever-increasing data, the frequency of electronic equipment has become higher and higher. At this time, the electrical performance of the circuit board will seriously affect the characteristic of the digital circuit. Therefore, newer requirements are put forward for the performance of the printed circuit board (PCB) substrate.

Passive Inter-Modulation, or PIM for short, is also called intermodulation distortion, which is caused by the nonlinear characteristics of various passive components in the radio frequency system. In a high-power, multi-channel system, the nonlinearity of these passive components will produce some frequency components relative to the operating frequency, and these frequency components and the operating frequency are mixed together to enter the operating system. If these useless frequency components are large enough, they will affect the normal operation of the communication system. When the spurious intermodulation signal falls in the frequency acceptance band of the base station, the sensitivity of the receiver will be reduced, which will lead to a reduction in the call quality or the carrier-to-interference ratio of the system, and the capacity of the communication system. PIM has become an important parameter that limits the system capacity.

The issue of passive intermodulation in the early stage mainly caused interference to a high-power microwave device such as a circulator, a waveguide, a coaxial connector, a duplexer, an attenuator, an antenna and the like. As printed circuit boards are more and more widely used in the field of microwave circuits to develop flat-panel integrated radio frequency front-ends, the increase in signal power makes the PIM issue of the PCB substrate itself a barrier to the development of high-performance radio frequency circuits. At present, the electronic communication technology is developing towards faster transmission speed, larger transmission capacity, and higher integration. In modern microwave communication circuits, high-power multi-channel transmitters, more sensitive receivers, shared antennas, complex modulation signals and dense communication frequency band all put forward higher performance requirements for the power capacity and PIM indicators in PCB circuit design and manufacturing than traditional PCB substrates. A low-PIM high-performance circuit substrate has become the foundation and key technology in this field.

CN205793612U and CN107197592A mainly select polytetrafluoroethylene (PTFE) as a dielectric insulating layer to make a low-PIM high-performance ceramic substrate.

However, there is still a need to provide a copper clad laminate with a low passive intermodulation value and a printed circuit board containing the copper clad laminate.

### SUMMARY

An object of the present disclosure is to provide a copper clad laminate having a passive intermodulation performance of less than −158 dBc (700 MHz/2600 MHz) and a printed circuit board prepared containing the copper clad laminate.

Another object of the present disclosure is to provide a copper clad laminate having a passive intermodulation performance of less than −158 dBc under the conditions of 700 MHz to 2600 MHz and capable of meeting the high-frequency and high-speed requirements in the field of electronic information, and a printed circuit board containing the copper clad laminate.

Upon in-depth and detailed research, the inventor of the present disclosure found that the iron, nickel, cobalt and molybdenum elements in the copper foil layer of the copper clad laminate will deteriorate the PIM of the printed circuit board. When the weight content of iron element in the copper foil layer is less than 10 ppm; the weight content of nickel element is less than 10 ppm; the weight content of cobalt element is less than 10 ppm; and the weight content of molybdenum element is less than 10 ppm, a printed circuit board with a lower PIM can be obtained. For example, a printed circuit board with a PIM value less than −158 dBc (700 MHz/2600 MHz) can be obtained.

The weight content of each element in the copper foil layer refers to the weight of that the element divided by the total weight of the copper foil.

In one aspect, the present disclosure provides a copper clad laminate, comprising:
a dielectric substrate layer, and
a copper foil layer being located on at least one surface of the dielectric substrate layer,
wherein, in the copper foil layer, the weight content of iron element is less than 10 ppm; the weight content of nickel element is less than 10 ppm; the weight content of cobalt element is less than 10 ppm; and the weight content of molybdenum element is less than 10 ppm.

In one embodiment, the copper clad laminate has a passive intermodulation value of less than −158 dBc at 700 MHz-2600 MHz.

In one embodiment, the matte side roughness of the copper foil is 0.5-3 μm.

In one embodiment, the dielectric substrate layer comprises a polymer matrix material; and a filler; wherein, based on the weight of the dielectric substrate layer, the polymer matrix material is 30 to 70 weight percent; and the filler is 30 to 70 weight percent.

In one embodiment, the polymer matrix material comprises one or more of a modified or unmodified polybutadiene resin, a modified or unmodified polyisoprene resin and a modified or unmodified polyarylether resin.

In one embodiment, the dielectric substrate layer has a dielectric constant less than 3.5 and a dissipation factor less than 0.006 at 10 GHz.

In one embodiment, the polybutadiene resin is a polybutadiene homopolymer resin or a polybutadiene copolymer resin.

In one embodiment, the polybutadiene copolymer resin is a polybutadiene-styrene copolymer resin.

In one embodiment, the modified polybutadiene resin is selected from one or more of a hydroxyl-terminated polybutadiene resin, a methacrylate-terminated polybutadiene resin, and a carboxylated polybutadiene resin.

In one embodiment, the polyisoprene resin is a polyisoprene homopolymer resin or a polyisoprene copolymer resin.

In one embodiment, the polyisoprene copolymer resin is a polyisoprene-styrene copolymer resin.

In one embodiment, the modified polyisoprene resin is a carboxylated polyisoprene resin.

In one embodiment, the modified polyarylether resin is selected from one or more of carboxyl functionalized polyarylether, methacrylate-terminated polyarylether, and vinyl-terminated polyarylether.

In one embodiment, the polymer matrix material further comprises one or more of co-curable polymers other than a polybutadiene resin, a polyisoprene resin and a polyarylether resin, a free radical curing monomer, an elastomer block copolymer, an initiator, a flame retardant, a viscosity modifier and a solvent.

In one embodiment, the dielectric substrate layer comprises a reinforcing material or no reinforcing material.

In one embodiment, the copper clad laminate further comprises a bonding layer and/or a resin film layer located between the copper foil and the dielectric substrate layer.

In one aspect, the present disclosure provides a printed circuit board containing the copper clad laminate described in any one of the above.

In one aspect, the present disclosure provides a circuit comprising the printed circuit board described above.

In one aspect, the present disclosure provides a multilayer circuit comprising the printed circuit board described above.

In one embodiment, a circuit or a multilayer circuit comprising the printed circuit board is used for an antenna.

According to the present disclosure, it is possible to provide a copper clad laminate having a passive intermodulation performance of less than −158 dBc (700 MHz/2600 MHz) and a printed circuit board containing the copper clad laminate by restricting the weight content of iron to less than 10 ppm, the weight content of nickel to less than 10 ppm, the weight content of cobalt to less than 10 ppm, and the weight content of molybdenum to less than 10 ppm in the copper foil layer.

In addition, a copper clad laminate having a passive intermodulation performance of less than −158 dBc (700 MHz/2600 MHz) and capable of meeting the high-frequency and high-speed requirements in the electronic information field and a printed circuit board containing the copper clad laminate can also be provided.

### DETAILED DESCRIPTION

The technical solutions in the examples of the present disclosure will be clearly and completely described below in conjunction with the specific embodiments of the present disclosure. Obviously, the described embodiments and/or examples are only a part of the embodiments and/or examples of the present disclosure, rather than all of the embodiments and/or examples. Based on the embodiments and/or examples of the present disclosure, every other embodiments and/or every other examples obtained by those ordinary skilled in the art without creative work fall within the protection scope of the present disclosure.

In the present disclosure, all numerical features refer to within the error range of the measurement, for example, within ±10%, or ±5%, or ±1% of the defined value.

The expressions “comprising”, “including” or “containing” mentioned in the present disclosure mean that, in addition to the aforementioned components, there may also be other components, and these other components endow the prepreg with different characteristics. In addition, the expressions “comprising”, “including” or “containing” mentioned in the present disclosure may also include “essentially consist of”, and may be replaced with “is” or “consists of”.

In the present disclosure, the amount, ratio, etc. are by weight, if not specifically indicated.

In the present disclosure, a copper foil layer may also be abbreviated as a copper foil.

The present disclosure discloses a copper clad laminate, comprising:
a dielectric substrate layer, and
a copper foil layer being located on at least one surface of the dielectric substrate layer,
wherein, in the copper foil layer, the weight content of iron element is less than 10 ppm; the weight content of nickel element is less than 10 ppm; the weight content of cobalt element is less than 10 ppm; and the weight content of molybdenum element is less than 10 ppm.

Preferably, the weight content of the iron element is less than or equal to 7 ppm, more preferably less than or equal to 5 ppm.

Preferably, the weight content of the nickel element is less than or equal to 7 ppm, more preferably less than or equal to 5 ppm.

Preferably, the weight content of the cobalt element is less than or equal to 7 ppm, more preferably less than or equal to 5 ppm.

Preferably, the weight content of the molybdenum iron element is less than or equal to 7 ppm, more preferably less than or equal to 5 ppm.

Further, in the copper foil layer, the sum of the weight contents of iron, nickel, cobalt and molybdenum elements may be less than or equal to 35 ppm, preferably less than or equal to 30 ppm, more preferably less than or equal to 18 ppm, and further preferably less than or equal to 12 ppm, and most preferably less than or equal to 5 ppm.

Upon in-depth and detailed research, the inventor of the present disclosure found that the iron, nickel, cobalt, and molybdenum elements in the copper foil layer of the copper clad laminate will deteriorate the PIM of the printed circuit board. When the weight content of iron element in the copper foil layer is less than 10 ppm; the weight content of nickel element is less than 10 ppm; the weight content of cobalt element is less than 10 ppm; and the weight content of molybdenum element is less than 10 ppm, a printed circuit board with a lower PIM can be obtained. For example, a printed circuit board with a PIM value less than −158 dBc (700 MHz/2600 MHz), preferably less than or equal to −160 dBc (700 MHz/2600 MHz), more preferably less than or equal to −163 dBc (700 MHz/2600 MHz) can be obtained.

The passive intermodulation value at 700 MHz-2600 MHz refers to the passive intermodulation value (PIM) measured by the reflection method on the copper clad laminate between 700 MHz and 2600 MHz.

The passive intermodulation values less than −158 dBc at 700 MHz-2600 MHz can also be expressed as −158 dBc (700 MHz/2600 MHz).

PIM can be measured as follows. Each sample is tested 9 times, each time an intermodulation model and a frequency are selected, the Summitek Instruments PIM analyzer is used to test, and the maximum value of the 9 test data is recorded, which is the PIM value of the sample. The circuit design length of the intermodulation model is 12 inches (but not limited to 12 inches) arc and zigzag circuits (it can also be straight lines or other arbitrary shapes), and the model thickness of samples are 10 mil, 20 mil and 30 mil, respectively corresponding to the line widths of 24 mil, 48 mil and 74 mil; the frequency is 700 MHz, 1900 MHz and 2600 MHz respectively. That is, the 9 test data are 3 data measured with the model thickness of 10 mil, the model line width of 24 mil and at 700 MHz, 1900 MHz and 2600 MHz, 3 data measured with the model thickness of 20 mil, the model linewidth of 48 mil at 700 MHz, 1900 MHz and 2600 MHz, and 3 data measured with the model thickness of 30 mil, the model line width of 74 mil at 700 MHz, 1900 MHz and 2600 MHz.

In an embodiment, the matte side roughness of the copper foil is 0.5-3 μm, so as to obtain a better signal integrity.

In one embodiment, the amount of iron, nickel, cobalt and molybdenum content in the copper foil is achieved by a post-treatment process of the electrolytic copper foil. A typical post-treatment process of electrolytic copper foil is as follows. Degreasing→Mater Washing→Pickling and Rust Removal→Mater Washing→Alloy Electroplating Liquid Plating→Mater Washing→Passivation→*Water Washing→*Drying. In the alloy electroplating liquid plating, there can be dissolved salts corresponding to iron, nickel, cobalt and molybdenum, such as iron sulfate, molybdenum sulfate, nickel sulfate, cobalt sulfate, iron nitrate, molybdenum nitrate, cobalt nitrate, nickel nitrate and etc. The content of the iron, nickel, cobalt and molybdenum in the copper foil in the electrolytic copper foil can be adjusted by controlling process parameters such as the concentration of salt corresponding to iron, nickel, cobalt and molybdenum elements in the alloy plating solution, current and temperature.

The thickness of the copper foil layer may be 0.1 to 10 OZ, preferably 0.2 to 5 OZ, and further preferably 0.5 to 2 OZ. 1 OZ means 35 microns.

The dielectric substrate layer may be formed from a resin composition comprising a polymer matrix material and a filler.

Wherein, based on the weight of the dielectric substrate layer, the polymer matrix material is 30 to 70 weight percent; and the filler is 30 to 70 weight percent.

Optionally, the dielectric substrate layer may or may not include a reinforcing material. In the case where a reinforcing material is included, a composition containing the polymer matrix material and the filler is attached to the reinforcing material to form a dielectric substrate layer. Preferably, the reinforcing material is a porous reinforcing material such as glass fiber.

Optionally, the polymer matrix material includes one or more of a modified or unmodified polybutadiene resin, a modified or unmodified polyisoprene resin, and a modified or unmodified polyarylether resin.

Optionally, the dielectric substrate layer made therefrom has a dielectric constant of less than about 3.5 and a dissipation factor of less than about 0.006 at 10 GHz, which can meet the high-frequency and high-speed requirements in the field of electronic information. Moreover, the PCB substrate having a dielectric constant of less than about 3.5 and a dissipation factor less than about 0.006 at 10 GHz puts forward higher performance requirements on the PIM index than the PCB substrate with a dielectric constant more than 3.5 and a dissipation factor more than 0.006.

Optionally, the relative amounts of various polymers such as polybutadiene polymer or polyisoprene polymer, and other polymers may depend on the specific copper foil layer used, the desired circuit material, and the properties of the circuit laminate and similar considerations. The use of polyarylether has been found to provide enhanced bondstrength of the copper foil to the dielectric metal layer. The use of polybutadiene polymer or polyisoprene polymer can improve the high temperature resistance of the laminate.

Optionally, the polybutadiene resin may include a polybutadiene homopolymer or copolymer resin. The polybutadiene copolymer resin may be a polybutadiene-styrene copolymer resin. The modified polybutadiene resin may be selected from one or more of a hydroxyl-terminated polybutadiene resin, a methacrylate-terminated polybutadiene resin, and a carboxylated polybutadiene resin.

Optionally, the polyisoprene resin may include a polyisoprene homopolymer resin or a polyisoprene copolymer resin. The polyisoprene copolymer resin may be a polyisoprene-styrene copolymer resin. The modified polyisoprene homopolymer resin or polyisoprene copolymer resin may be a carboxylated polyisoprene resin.

Optionally, the modified polyarylether resin may be one or more of carboxyl functionalized polyarylether, methacrylate-terminated polyarylether, and vinyl-terminated polyarylether.

Specifically, polybutadiene resins and polyisoprene resins include homopolymers and copolymers containing units derived from butadiene, isoprene, or a mixture thereof. Units derived from other copolymerizable monomers may also be present in the resin, for example, optionally in grafted form. Exemplary copolymerizable monomers include, but are not limited to, vinyl aromatic monomers, such as substituted and unsubstituted monovinyl aromatic monomers, such as styrene, 3-methylstyrene, 3,5-diethylstyrene, 4-n-propylstyrene, alpha-methylstyrene, alpha-methylvinyltoluene, p-hydroxystyrene, p-methoxystyrene, alpha-chlorostyrene, alpha-bromostyrene, dichlorostyrene, dibromostyrene, tetrachlorostyrene and the like; and substituted and unsubstituted divinyl aromatic monomers such as divinylbenzene, divinyl toluene and the like. Compositions containing at least one of the aforementioned copolymerizable monomers can also be used. Exemplary thermosetting polybutadiene and/or polyisoprene resins include, but are not limited to, butadiene homopolymers, isoprene homopolymers, butadiene-vinyl aromatic copolymers such as butadiene-styrene, isoprene-vinyl aromatic copolymers such as isoprene-styrene copolymers and etc., for example, styrene-butadiene copolymer Ricon100 from Crayvally, or polybutadiene B-1000 from Nippon Soda.

Optionally, the polybutadiene resin and/or the polyisoprene resin may be modified. For example, the resin may be a hydroxyl-terminated resin, a methacrylate-terminated resin, or a carboxylate-terminated resin, and the like. The polybutadiene resin and the polyisoprene resin may be epoxy-, maleic anhydride-, or urethane-modified butadiene or isoprene resin. The polybutadiene resin and the polyisoprene resin can also be cross-linked, for example, with divinyl aromatic compounds such as divinylbenzene, such as polybutadiene-styrene cross-linked with divinylbenzene. Exemplary resins are broadly classified as “polybutadiene” by their manufacturers such as Nippon Soda Co. (Tokyo, Japan) and Cray Valley Hydrocarbon Specialty Chemicals (Exton, Pa., USA). Mixtures of resins can also be used, such as a mixture of polybutadiene homopolymer and poly(butadiene-isoprene) copolymer. Combinations containing syndiotactic polybutadiene can also be used.

Optionally, the polybutadiene polymer or polyisoprene polymer may be carboxy functionalized. Functionalization can be accomplished using the following multifunctional compounds that have (i) carbon-carbon double bonds or carbon-carbon triple bonds in the molecule; and (ii) one or more carboxyl groups, including carboxylic acid, acid anhydride, amide, ester or acid halide. A specific carboxyl group is a carboxylic acid or an ester. Examples of polyfunctional compounds that can provide carboxylic acid functional groups include maleic acid, maleic anhydride, fumaric acid, and citric acid. In particular, maleic anhydride-added polybutadiene can be used for thermosetting compositions. Suitable maleic anhydride polybutadiene polymers are commercially available, for example, from Cray Valley, under the trade names RICON130MA8, RICON130MA13, RICON130MA20, RICON131MA5, RICON131MA10, RICON131MA17, RICON131MA20 and RICON156MA17. Suitable maleic anhydride polybutadiene-styrene copolymers are commercially available, for example, from Crayvally, under the trade name RICON184MA6.

Optionally, the thermosetting polybutadiene and/or polyisoprene resin may be a liquid or a solid state at room temperature. Suitable liquid resins may have a number average molecular weight more than about 5000, but generally have a number average molecular weight less than about 5000 (most preferably from about 1000 to about 3000). Thermosetting polybutadiene and/or polyisoprene resins include resins with at least 90% by weight of 1,2-addition, which exhibit a greater crosslinking density after curing due to the large number of prominent vinyl groups can be used for cross-linking.

Optionally, the polybutadiene and/or polyisoprene resin may be present in the polymer matrix composition in an amount of up to 100 wt %, particularly up to about 75 wt %, more particularly about 10 wt % to 70 wt %, and even more particularly from about 20 wt % to about 60 wt % or 70 wt % relative to the total resin system.

Optionally, the modified polyphenylene ether resin is selected from one or a mixture of at least two of a polyphenylene ether resin with acryloyl groups at both ends as modifying groups, a polyphenylene ether resin with styrene groups at both ends as modifying groups, and a polyphenylene ether resins with vinyl groups at both ends as modifying groups.

Preferably, the modified polyphenylene ether resin is represented by the following Formula (1):

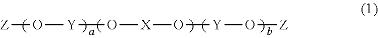

In formula (1), a and b are each independently an integer from 1 to 30;
Z is a group represented by Formula (2) or (3):

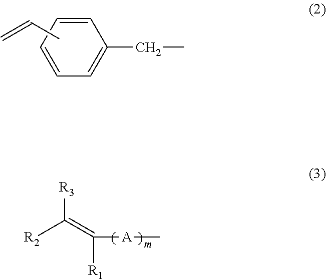

in formula (3), A is an arylene group having 6 to 30 carbon atoms, a carbonyl group, or an alkylene group having 1 to 10 carbon atoms; m is an integer of 0 to 10, and R₁ to R₃ are each independently a hydrogen atom or an alkyl group having 1 to 10 carbon atoms;
—(—O—Y—)— in formula (1) is a group represented by Formula (4):

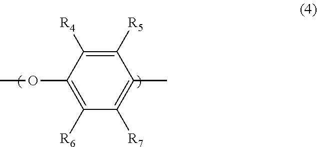

in formula (4), R₄ and R₆ are each independently a hydrogen atom, a halogen atom, an alkyl group having 1 to 10 carbon atoms, or a phenyl group; and R₅ and R₇ are each independently a hydrogen atom, a halogen atom, an alkyl group having 1 to 10 carbon atoms or phenyl group;
—(—O—X—O—)— in Formula (1) is a group represented by Formula (5):

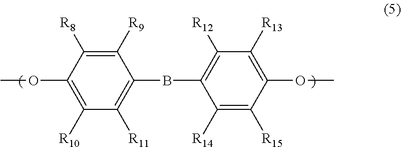

in Formula (5), R₈, R₉, R₁₀, R₁₁, R₁₂, R₁₃, R₁₄ and R₁₅ are each independently a hydrogen atom, a halogen atom, an alkyl group having 1 to 10 carbon atoms, or a phenyl group; and B is an arylene group having 6 to 30 carbon atoms, an alkylene group having 1 to 10 carbon atoms, —O—, —CO—, —SO—, —CS— or —SO₂—.

The alkyl group having 1 to 10 carbon atoms is preferably an alkyl group having 1 to 8 carbon atoms, further preferably an alkyl group having 1 to 6 carbon atoms, and further more preferably an alkyl group having 1 to 4 carbon atoms. Examples of the alkyl group having 1 to 8 carbon atoms may include methyl, ethyl, propyl, butyl, pentyl, hexyl, heptyl and octyl, as well as cyclopropyl, cyclobutyl, cyclopentyl and cyclohexyl. Where there are isomeric forms, all isomeric forms are included. For example, the butyl group may include n-butyl, isobutyl, and tert-butyl.

Examples of the arylene group having 6 to 30 carbon atoms may include phenylene group, naphthylene group, and anthrylene group.

The alkylene group having 1 to 10 carbon atoms is preferably an alkylene group having 1 to 8 carbon atoms, more preferably an alkylene group having 1 to 6 carbon atoms, and further more preferably an alkylene group having 1 to 4 carbon atoms. Examples of the alkylene group having 1 to 10 carbon atoms may include methylene, ethylidene, propylidene, butylidene, pentylidene, hexylidene, heptylidene, octylidene, nonylidene and decylidene, as well as cyclopropylidene, cyclobutylidene, cyclopentylidene and cyclohexylidene. Where there are isomeric forms, all isomeric forms are included.

Examples of the halogen atom may include fluorine atom, chlorine atom, bromine atom, and iodine atom.

Preferably, the number average molecular weight of the polyphenylene ether resin may be 500 to 10000 g/mol, preferably 800 to 8000 g/mol, further preferably 1000 to 7000 g/mol. Exemplary polyphenylene ethers can be methacrylate-modified polyphenylene ether SA9000 from Sabic, or styryl-modified polyphenylene ether St-PPE-1 from Mitsubishi Chemical Corporation.

Optionally, the filler may be selected from one or more of crystalline silica, fused silica, spherical silica, boron nitride, aluminum hydroxide, titanium dioxide, strontium titanate, barium titanate, aluminum oxide, magnesium oxide, barium sulfate, borosilicate, aluminosilicate, and talc. The filler may be in the form of solid, porous or hollow particles. In order to improve the adhesion between the filler and the polymer, the filler may be treated with one or more coupling agents such as silanes, zirconates or titanates. In use, the amount of filler usually accounts for 30 to 70 weight percent of the dielectric substrate layer. An exemplary non-hollow inorganic filler may be DQ2028V from Jiangsu Novoray. An exemplary hollow inorganic filler may be iM16K from 3M.

For specific performance or process changes, other polymers that can be co-cured with thermosetting polybutadiene and/or polyisoprene resin and/or polyphenylene ether resin can be added into the polymer matrix material. For example, in order to improve the dielectric strength and the stability of mechanical properties of the electrical substrate material over time, ethylene-propylene elastomer with a lower molecular weight can be used in the resin system. The ethylene-propylene elastomers used herein are copolymers, terpolymers or other polymers mainly containing ethylene and propylene. Ethylene-propylene elastomers can be further classified as EPM copolymers (i.e. copolymers of ethylene and propylene monomers) or EPDM terpolymers (i.e. terpolymers of ethylene, propylene and diene monomers). In particular, the ethylene-propylene-diene terpolymer rubber has a saturated main chain, and unsaturation in the main chain that can be easily crosslinked. A liquid ethylene-propylene-diene terpolymer rubber in which the diene is dicyclopentadiene can be used.

Optionally, the molecular weight of the ethylene-propylene rubber may be less than a viscosity average molecular weight of 10,000. The ethylene-propylene rubber is present in an effective amount to maintain the properties of the matrix material, particularly the dielectric strength and the stability of mechanical properties over time. Generally, this amount is up to about 20 wt %, more particularly from about 4 to about 20 wt %, and even more particularly from about 6 to about 12 wt %, relative to the total weight of the polymer matrix composition. An exemplary ethylene-propylene rubber may be Trilene 67 from lion Copolymer.

Optionally, another type of co-curable polymer is an elastomer containing unsaturated polybutadiene or polyisoprene. The component may be mainly 1,3-addition butadiene or isoprene and ethylenically unsaturated monomers such as vinyl aromatic compounds such as styrene or alpha-methyl styrene, acrylate or methyl acrylate such as methyl methacrylate, or random copolymers or block copolymers of acrylonitrile. Elastomers can be solid, thermoplastic form of linear or graft type block copolymers containing polybutadiene or polyisoprene blocks, as well as thermoplastic blocks that can be derived from monovinyl aromatic monomers such as styrene or alpha-methylstyrenem. This type of block copolymer includes styrene-butadiene-styrene triblock copolymers, styrene-butadiene diblock copolymers, and mixed triblock and diblock copolymers containing styrene and butadiene. Exemplary Kraton D1118 is a copolymer containing mixed diblock/triblock of styrene and butadiene.

Generally, the elastomer component containing unsaturated polybutadiene- or polyisoprene—is present in the resin system in an amount of from about 2 wt. % to about 60 wt. %, more particularly about 5 wt. % to about 50 wt. %, or even more specifically from about 10 wt. % to about 40 or 50 wt. % relative to the total polymer matrix composition.

For specific performance or process changes, other co-curable polymers other than polybutadiene resins, polyisoprene resins and polyarylether resins may be added, including but not limited to homopolymers or copolymers of ethylene, such as polyethylene and ethylene oxide copolymers; natural rubber; norbornene polymers such as polydicyclopentadiene; hydrogenated styrene-isoprene-styrene copolymers and butadiene-acrylonitrile copolymers; unsaturated polyester, etc. The level of these copolymers is generally less than 50 wt. % of the total polymer in the matrix composition.

Free radical curable monomers can also be added for specific performance or process changes, for example to increase the crosslinking density of the resin system after curing. Exemplary monomers that can be used as suitable crosslinking agents include, for example, di-, tri-, or higher ethylenically unsaturated monomers such as divinylbenzene, triallyl cyanurate, diallyl terephthalate esters, and multifunctional acrylate monomers (such as resins, available from SartomerUSA (Newtown Square, Pa.)), or combinations thereof, which are all commercially available. In use, the crosslinking agent is present in the resin system in an amount of up to about 20 wt. %, particularly 1 to 15 wt. % of the total polymer matrix composition.

An initiator can be added to the resin system to accelerate the curing reaction of the polyene having olefin reaction sites. The particularly useful initiator is an organic peroxide, for example, any one or a mixture of at least two of dicumyl peroxide, dilauroyl peroxide, cumyl peroxyne decanoate, tert-butyl peroxyne decanoate, pivalate peroxypivalate, tert-butyl peroxypivalate, tert-butylperoxy isobutyrate, tert-butylperoxy-3,5,5-trimethylhexanoate, tert-butyl peroxyacetate, tert-butyl peroxybenzoate, 1,1-di-tert-butylperoxy-3,5,5-trimethylcyclohexane, 1,1-di-tert-butylperoxy-cyclohexane, 2,2-bis(tert-butylperoxy)butane, bis(4-tert-butylcyclohexyl)-peroxydicarbonate, hexadecyl peroxydicarbonate, tetradecyl peroxydicarbonate, di-tertpentyl peroxide, dicumyl peroxide, bis(tert-butylperoxyisopropyl)-benzene, 2,5-dimethyl-2,5-di-tert-butylperoxy-hexane, 2,5-dimethyl-2,5-di-tert-butylperoxyhexyne, dicumyl hydroperoxide, tert-pentyl hydroperoxide, tert-butyl hydroperoxide, tert-butyl peroxycarbonate-2-ethylhexanoate, tert-butyl 2-ethylhexyl peroxycarbonate, butyl 4,4-di(tert-butylperoxy)valerate, methyl ethyl ketone peroxide and cyclohexane peroxide, which are all commercially available. An carbon-carbon initiator can also be used in the resin system, such as 2,3-dimethyl-2,3-diphenylbutane. The initiator can be used alone or in combination. A typical initiator amount is about 1.5 to about 10 wt. % of the total polymer matrix composition.

A flame retardant can be added to the resin system to make electronic components have flame retardation properties. The flame retardant may be selected from one or a mixture of at least two of halogen flame retardants, phosphorous flame retardants.

Optionally, the brominated flame retardant can be selected from any one or a mixture of at least two of decabromodiphenyl ether, hexabromobenzene, decabromodiphenylethane, ethylenebistetrabromophthalimide.

Optionally, the phosphorus-based flame retardant can be selected from one or a mixture of at least two of tris(2,6-dimethylphenyl)phosphine, 10-(2,5-dihydroxy-phenyl)-9,10-dihydro-9-oxa-10-phosphinphenanthrene-10-oxide, 2,6-bis(2,6-dimethylphenyl)phosphinobenzene or 10-phenyl-9,10-dihydro-9-oxa-10-phosphinphenanthrene-10-oxide.

An exemplary bromine-containing flame retardant may be BT-93 W from Albemarle, USA.

An exemplary bromine-containing flame retardant may be XP-7866 from Albemarle, USA.

As a solvent of the polymer matrix material in the present disclosure, there is not particularly limitation. Specific examples include alcohols such as methanol, ethanol, butanol and the like; ethers such as ethyl cellosolve, butyl cellosolve, ethylene glycol-methyl ether, carbitol, butyl carbitol and the like; ketones such as acetone, butanone, methyl ethyl ketone, methyl isobutyl ketone, cyclohexanone and the like; aromatic hydrocarbons such as toluene, xylene, mesitylene and the like; esters such as ethoxyethyl acetate, ethyl acetate and the like; nitrogen-containing solvents such as N,N-dimethylformamide, N,N-dimethylacetamide, N-methyl-2-pyrrolidone and the like.

The above-mentioned solvents can be used alone or in combination of two or more, preferably combining aromatic hydrocarbon solvents, such as toluene, xylene and mesitylene, with ketone solvents, such as acetone, butanone, methyl ethyl ketone, methyl isobutyl ketone, cyclohexanone and the like. Those skilled in the art can choose the amount of the solvent to be used according to their own experience, so that the resultant resin glue solution has a viscosity suitable for use.

The viscosity of the resin composition can be adjusted by adding a viscosity modifier (selected based on the compatibility with the mixture of the specific polymer matrix material) to delay the separation of the filler from the dielectric composite material, that is, settling or floating; and to provide a dielectric composite material with a viscosity compatible with conventional laminating equipment. Exemplary viscosity modifiers include, for example, polyacrylic acid compounds, nanofillers, ethylene-propylene rubbers, and the like.

Various additives may also be contained. Specific examples include an antioxidant, a heat stabilizer, an antistatic agent, an ultraviolet absorber, a pigment, a colorant, a lubricant, and the like. These various additives can be used alone, or in combination of two or more.

Optionally, the dielectric substrate layer may be a resin film layer obtained by coating the release film with a varnish that is a mixture of the polymer matrix material, which optionally contains polybutadiene resin, polyisoprene resin, polyarylether resin, other co-curable polymers, free radical curing monomers, elastomer block copolymers, initiator, flame retardant, viscosity modifier, solvent, etc., and the filler, or a reinforcing material-containing dielectric substrate layer prepared by impregnating or coating the reinforcing material with the varnish of a combination of the polymer matrix material and filler.

The reinforcing material optionally includes suitable fibers, in particular glass fibers (E and NE glass) or non-woven or woven thermally stable nets of high-temperature polyester fibers. Such thermally stable fiber reinforcements provide copper clad laminates with relatively high curing shrinkage and mechanical strength.

In the copper clad laminate of the present disclosure, the copper foil and the dielectric substrate layer may be in direct contact, and a bonding layer and/or a resin film layer may also be included between the copper foil and the dielectric substrate layer to improve the adhesion between the copper foil and the dielectric substrate layer, or to improve the dielectric performance thereof. The bonding layer is applied to the surface of the copper foil or dielectric substrate layer in the form of a solution to provide a coating weight of 2 to 15 g/m² to obtain the bonding layer. The resin film layer may be applied to the surface of the copper foil or the dielectric substrate layer in the form of a solution to provide a coating weight of 2 to 15 g/m² to obtain the resin film layer.

In the copper clad laminate of the present disclosure, the resin film layer may also be included in the middle of the dielectric substrate layer.

The bonding layer and/or the resin film layer may have the same composition as or different from the dielectric substrate layer, and may be uncured, partially cured or fully cured.

The exemplary preparation method: the dielectric substrate layer was prepared by impregnating or coating the reinforcing material (E glass fabric) with the varnish of a combination of the polymer matrix material optionally comprising polybutadiene resin, polyisoprene resin, polyarylether resin, other co-curable polymers, free radical curing monomers, elastomer block copolymers, initiators, flame retardant, viscosity modifier, solvent and etc., with the filler, passed through the rollers to control the appropriate unit weight, and sheet-dried in an oven to remove the solvent. One or more dielectric substrate layers were overlapped with copper foils on the upper and lower sides, vacuum laminated and cured in a press for 60-120 min with a curing pressure of 25-50 Kg/cm² and a curing temperature 180-220° C. to make copper clad laminates.

In another aspect, the present disclosure provides a circuit including the printed circuit board described above.

In yet another aspect, the present disclosure provides a multilayer circuit including the printed circuit board described above.

In one embodiment, a circuit or a multilayer circuit including the printed circuit board is used for an antenna.

According to the present disclosure, it is possible to provide a copper clad laminate having a passive intermodulation performance of less than −158 dBc (700 MHz/2600 MHz) and a printed circuit board containing the copper clad laminate by restricting the weight content of iron to less than 10 ppm, the weight content of nickel to less than 10 ppm, the weight content of cobalt to less than 10 ppm, and the weight content of molybdenum to less than 10 ppm in the copper foil layer.

In addition, a copper clad laminate having a passive intermodulation performance of less than −158 dBc (700 MHz/2600 MHz) and capable of meeting the high-frequency and high-speed requirements in the electronic information field and a printed circuit board containing the copper clad laminate can also be provided.

The technical solutions of the present disclosure will be further described below through specific embodiments. In the following examples and comparative examples, if not specifically indicated, percentages, ratios, etc. are by weight.

### EXAMPLE

The raw materials selected for the high-speed electronic circuit substrate prepared by the example of the present disclosure are shown in the following table.

TABLE 1

| | Product name | |
|---|---|---|
| Manufacturer | or brand | Material description |
| Sabic | SA90 | Hydroxy-terminated |
| | | polyphenylene ether resin |
| Sabic | SA9000 | Methacrylate modified |
| | | polyphenylene ether resin |
| Mitsubishi | St-PPE-1 | Styrene-based modified |
| Chemical | | polyphenylene ether resin |
| Crayvally | Ricon100 | Styrene-butadiene copolymer |
| Crayvally | Ricon130MA8 | Maleic anhydride polybutadiene resin |
| Kraton | D1118 | Styrene-butadiene-styrene block |
| | | copolymer |
| Lion Copolymer | Trilene 67 | Ethylene Propylene Elastomer |
| Nippon Soda | B1000 | Polybutadiene resin |
| Shanghai | DCP | Dicumyl peroxide |
| Gaoqiao | | |
| Akzo Nobel | Perkadox 30 | 2,3-dimethyl-2,3-diphenylbutane |
| Jiangsu | DQ1028L | Fused silica powder |
| Novoray | | |
| Albemarle | BT-93W | Bromine-containing flame retardant |
| Albemarle | XP-7866 | Phosphorus-containing flame retardant |
| 3M | iM16K | Hollow borosilicate microsphere |
| Shanghai | 1078 | Glass fiber fabric |
| Gracefabric | | |

### Example 1

20 g of polybutadiene resin B1000, 5 g of styrene-butadiene-styrene block copolymer D1118, 4 g of ethylene propylene elastomer Trilene 67, 1 g of maleic anhydride polybutadiene resin Ricon130MA8, 1 g 2,3-dimethyl-2,3-diphenylbutane Perkadox 30, 12 g bromine-containing flame retardant BT-93 W and 70 g inorganic filler DQ2028L were dissolved in a toluene solvent, and adjusted to a viscosity of 50 s (testing by using No. 4 viscosity cup). 1078 glass fiber fabric was impregnated with the varnish, controlled to have the unit weight of 190 g by passing through the rollers and sheet-dried in an oven to remove the toluene solvent to obtain 1078 prepreg. 6 sheets of 1078 prepreg were overlapped with copper foil having a thickness of 1 OZ on the upper and lower sides, vacuum laminated and cured in a press for 90 min with a curing pressure 25 Kg/cm² and a curing temperature of 180° C. to obtain a copper clad laminate. The composition and amount of the dielectric substrate layer of the copper clad laminate, the thickness of the copper foil layer, the roughness of the matte side and the content of iron, nickel, cobalt and molybdenum, the amount of filler and the physical properties of the copper clad laminate are shown in Table 2.

### Examples 2-16 and Comparative Examples 1-16

The respective dielectric substrates and copper clad laminates of Examples 2-16 and Comparative Examples 1-16 were prepared in the same manner as in Example 1, with the differences being the components and amounts of the dielectric substrate layer of the copper clad laminate as well as the thickness of the copper foil layer, the roughness of the matte side and the contents of iron, nickel, cobalt and molybdenum, the amount of filler and the physical properties of the copper clad laminate as shown in Table 2-5, respectively. In Table 2-5, the unit of the components of the dielectric substrate layer including the filler is grams.

TABLE 2

| | | Example 1 | | Example 2 | | Example 3 | | Example 4 | | Example 5 | | Example 6 | | Example 7 | | Example 8 | |
|---|---|---|---|---|---|---|---|---|---|---|---|---|---|---|---|---|---|
| Copper | Copper foil sample | Sample 1 | | Sample 2 | | Sample 3 | | Sample 4 | | Sample 5 | | Sample 6 | | Sample 7 | | Sample 8 | |
| foil | Copper foil thickness | 1 | OZ | 1 | OZ | 1 | OZ | 1 | OZ | 1 | OZ | 1 | OZ | 1 | OZ | 1 | OZ |
| | Matte side roughness | 2 | μm | 1.5 | μm | 1.0 | μm | 2 | μm | 1.5 | μm | 1.0 | μm | 2 | μm | 2 | μm |
| | of copper foil | | | | | | | | | | | | | | | | |

| | | | | | | | | | |
|---|---|---|---|---|---|---|---|---|---|
| | Iron (ppm) | 0 | 0 | 0 | 2 | 4 | 5 | 7 | 9 |
| | Nickel (ppm) | 1 | 3 | 2 | 2 | 4 | 5 | 8 | 9 |
| | Cobalt (ppm) | 0 | 0 | 3 | 3 | 5 | 7 | 6 | 9 |
| | Molybdenum (ppm) | 0 | 0 | 0 | 4 | 5 | 6 | 7 | 9 |
| Dielectric | B1000 | 20 | 30 | 40 | 0 | 0 | 0 | 0 | 0 |
| substrate | Ricon100 | 0 | 0 | 0 | 15 | 25 | 35 | 15 | 15 |
| layer | SA9000 | 0 | 0 | 0 | 15 | 25 | 35 | 20 | 20 |
| | St-PPE-1 | 0 | 0 | 0 | 0 | 0 | 0 | 15 | 15 |
| | D1118 | 5 | 10 | 20 | 0 | 0 | 0 | 0 | 0 |
| | Trilene 67 | 4 | 9 | 9 | 0 | 0 | 0 | 0 | 0 |
| | Ricon130MA8 | 1 | 1 | 1 | 0 | 0 | 0 | 0 | 0 |
| | DCP | 0 | 0 | 0 | 1 | 1.5 | 2.0 | 1.5 | 1.5 |
| | Perkadox 30 | 1.0 | 1.5 | 2.0 | 0 | 0 | 0 | 0 | 0 |
| | BT-93W | 12 | 16 | 18 | 8 | 12 | 16 | 12 | 0 |
| | XP-7866 | 0 | 0 | 0 | 0 | 0 | 0 | 0 | 12 |
| Filler | DQ2028L | 70 | 50 | 30 | 70 | 50 | 30 | 50 | 50 |
| | iM16K | 0 | 0 | 0 | 0 | 0 | 0 | 0 | 0 |
| | PIM (dBC) | −167 | −165 | −164 | −162 | −162 | −160 | −159 | −159 |
| | Dk | 3.6 | 3.4 | 3.2 | 3.7 | 3.5 | 3.2 | 3.5 | 3.5 |
| | Df | 0.0030 | 0.0030 | 0.0030 | 0.0035 | 0.0035 | 0.0035 | 0.0035 | 0.0035 |

TABLE 3

| | | Example 9 | | Example 10 | | Example 11 | | Example 12 | | Example 13 | | Example 14 | | Example 15 | | Example 16 | |
|---|---|---|---|---|---|---|---|---|---|---|---|---|---|---|---|---|---|
| Copper | Copper foil sample | Sample 1 | | Sample 2 | | Sample 3 | | Sample 4 | | Sample 5 | | Sample 6 | | Sample 7 | | Sample 8 | |
| foil | Copper foil thickness | 1 | OZ | 1 | OZ | 1 | OZ | 1 | OZ | 1 | OZ | 1 | OZ | 1 | OZ | 1 | OZ |
| | Matte side roughness | 2 | μm | 1.5 | μm | 1.0 | μm | 2 | μm | 1.5 | μm | 1.0 | μm | 2 | μm | 2 | μm |
| | of copper foil | | | | | | | | | | | | | | | | |

| | | | | | | | | | |
|---|---|---|---|---|---|---|---|---|---|
| | Iron (ppm) | 0 | 0 | 0 | 2 | 4 | 5 | 7 | 9 |
| | Nickel (ppm) | 1 | 3 | 2 | 2 | 4 | 5 | 8 | 9 |
| | Cobalt (ppm) | 0 | 0 | 3 | 3 | 5 | 7 | 6 | 9 |
| | Molybdenum (ppm) | 0 | 0 | 0 | 4 | 5 | 6 | 7 | 9 |
| Dielectric | B1000 | 20 | 30 | 40 | 0 | 0 | 0 | 0 | 0 |
| substrate | Ricon100 | 0 | 0 | 0 | 15 | 25 | 35 | 15 | 15 |
| layer | SA9000 | 0 | 0 | 0 | 15 | 25 | 35 | 20 | 20 |
| | St-PPE-1 | 0 | 0 | 0 | 0 | 0 | 0 | 15 | 15 |
| | D1118 | 5 | 10 | 20 | 0 | 0 | 0 | 0 | 0 |
| | Triene 67 | 4 | 9 | 9 | 0 | 0 | 0 | 0 | 0 |
| | Ricon130MA8 | 1 | 1 | 1 | 0 | 0 | 0 | 0 | 0 |
| | DCP | 0 | 0 | 0 | 1 | 1.5 | 2.0 | 1.5 | 1.5 |
| | Perkadox 30 | 1.0 | 1.5 | 2.0 | 0 | 0 | 0 | 0 | 0 |
| | BT-93W | 12 | 16 | 18 | 8 | 12 | 16 | 12 | 0 |
| | XP-7866 | 0 | 0 | 0 | 0 | 0 | 0 | 0 | 12 |
| Filler | DQ2028L | 59 | 42 | 25 | 59 | 42 | 25 | 42 | 42 |
| | iM16K | 11 | 8 | 5 | 11 | 8 | 5 | 8 | 8 |
| | PIM (dBC) | −167 | −166 | −165 | −162 | −162 | −161 | −159 | −159 |
| | Dk | 3.0 | 2.9 | 2.8 | 3.1 | 3.0 | 2.9 | 3.0 | 3.0 |
| | Df | 0.0030 | 0.0030 | 0.0030 | 0.0035 | 0.0035 | 0.0035 | 0.0035 | 0.0035 |

TABLE 4

| | | Comparative | | Comparative | | Comparative | | Comparative | | Comparative | | Comparative | | Comparative | | Comparative | |
|---|---|---|---|---|---|---|---|---|---|---|---|---|---|---|---|---|---|
| | | Example 1 | | Example 2 | | Example 3 | | Example 4 | | Example 5 | | Example 6 | | Example 7 | | Example 8 | |
| Copper | Copper foil sample | Comparative | | Comparative | | Comparative | | Comparative | | Comparative | | Comparative | | Comparative | | Comparative | |
| foil | | Sample 1 | | Sample 2 | | Sample 3 | | Sample 4 | | Sample 5 | | Sample 6 | | Sample 7 | | Sample 8 | |
| | Copper foil thickness | 1 | OZ | 1 | OZ | 1 | OZ | 1 | OZ | 1 | OZ | 1 | OZ | 1 | OZ | 1 | OZ |
| | Matte side roughness | 2 | μm | 1.5 | μm | 1.0 | μm | 2 | μm | 1.5 | μm | 1.0 | μm | 2 | μm | 2 | μm |
| | of copper foil | | | | | | | | | | | | | | | | |

| | | | | | | | | | |
|---|---|---|---|---|---|---|---|---|---|
| | Iron (ppm) | 0 | 0 | 0 | 2 | 10 | 5 | 7 | 10 |
| | Nickel (ppm) | 10 | 13 | 10 | 2 | 4 | 5 | 8 | 10 |
| | Cobalt (ppm) | 0 | 0 | 3 | 3 | 5 | 10 | 10 | 10 |
| | Molybdenum (ppm) | 0 | 0 | 0 | 10 | 5 | 6 | 7 | 10 |
| Dielectric | B1000 | 20 | 30 | 40 | 0 | 0 | 0 | 0 | 0 |
| substrate | Ricon100 | 0 | 0 | 0 | 15 | 25 | 35 | 15 | 15 |
| layer | SA9000 | 0 | 0 | 0 | 15 | 25 | 35 | 20 | 20 |
| | St-PPE-1 | 0 | 0 | 0 | 0 | 0 | 0 | 15 | 15 |
| | D1118 | 5 | 10 | 20 | 0 | 0 | 0 | 0 | 0 |
| | Triene 67 | 4 | 9 | 9 | 0 | 0 | 0 | 0 | 0 |
| | Ricon130MA8 | 1 | 1 | 1 | 0 | 0 | 0 | 0 | 0 |
| | DCP | 0 | 0 | 0 | 1 | 1.5 | 2.0 | 1.5 | 1.5 |
| | Perkadox 30 | 1.0 | 1.5 | 2.0 | 0 | 0 | 0 | 0 | 0 |
| | BT-93W | 12 | 16 | 18 | 8 | 12 | 16 | 12 | 0 |
| | XP-7866 | 0 | 0 | 0 | 0 | 0 | 0 | 0 | 12 |
| Filler | DQ2028L | 70 | 50 | 30 | 70 | 50 | 30 | 50 | 50 |
| | iM16K | 0 | 0 | 0 | 0 | 0 | 0 | 0 | 0 |
| | PIM (dBC) | −145 | −140 | −145 | −142 | −144 | −135 | −138 | −149 |
| | Dk | 3.6 | 3.4 | 3.2 | 3.7 | 3.5 | 3.2 | 3.5 | 3.5 |
| | Df | 0.0030 | 0.0030 | 0.0030 | 0.0035 | 0.0035 | 0.0035 | 0.0035 | 0.0035 |

TABLE 5

| | | Comparative | | Comparative | | Comparative | | Comparative | | Comparative | | Comparative | | Comparative | | Comparative | |
|---|---|---|---|---|---|---|---|---|---|---|---|---|---|---|---|---|---|
| | | Example 9 | | Example 10 | | Example 11 | | Example 12 | | Example 13 | | Example 14 | | Example 15 | | Example 16 | |
| Copper | Copper foil sample | Comparative | | Comparative | | Comparative | | Comparative | | Comparative | | Comparative | | Comparative | | Comparative | |
| foil | | Sample 1 | | Sample 2 | | Sample 3 | | Sample 4 | | Sample 5 | | Sample 6 | | Sample 7 | | Sample 8 | |
| | Copper foil thickness | 1 | OZ | 1 | OZ | 1 | OZ | 1 | OZ | 1 | OZ | 1 | OZ | 1 | OZ | 1 | OZ |
| | Matte side roughness | 2 | μm | 1.5 | μm | 1.0 | μm | 2 | μm | 1.5 | μm | 1.0 | μm | 2 | μm | 2 | μm |
| | of copper foil | | | | | | | | | | | | | | | | |

| | | | | | | | | | |
|---|---|---|---|---|---|---|---|---|---|
| | Iron (ppm) | 0 | 0 | 0 | 2 | 10 | 5 | 7 | 10 |
| | Nickel (ppm) | 10 | 13 | 10 | 2 | 4 | 5 | 8 | 10 |
| | Cobalt (ppm) | 0 | 0 | 3 | 3 | 5 | 10 | 10 | 10 |
| | Molybdenum (ppm) | 0 | 0 | 0 | 10 | 5 | 6 | 7 | 10 |
| Dielectric | B1000 | 20 | 30 | 40 | 0 | 0 | 0 | 0 | 0 |
| substrate | Ricon100 | 0 | 0 | 0 | 15 | 25 | 35 | 15 | 15 |
| layer | SA9000 | 0 | 0 | 0 | 15 | 25 | 35 | 20 | 20 |
| | St-PPE-1 | 0 | 0 | 0 | 0 | 0 | 0 | 15 | 15 |
| | D1118 | 5 | 10 | 20 | 0 | 0 | 0 | 0 | 0 |
| | Triene 67 | 4 | 9 | 9 | 0 | 0 | 0 | 0 | 0 |
| | Ricon130MA8 | 1 | 1 | 1 | 0 | 0 | 0 | 0 | 0 |
| | DCP | 0 | 0 | 0 | 1 | 1.5 | 2.0 | 1.5 | 1.5 |
| | Perkadox 30 | 1.0 | 1.5 | 2.0 | 0 | 0 | 0 | 0 | 0 |
| | BT-93W | 12 | 16 | 18 | 8 | 12 | 16 | 12 | 0 |
| | XP-7866 | 0 | 0 | 0 | 0 | 0 | 0 | 0 | 12 |
| Filler | DQ2028L | 59 | 42 | 25 | 59 | 42 | 25 | 42 | 42 |
| | iM16K | 11 | 8 | 5 | 11 | 8 | 5 | 8 | 8 |
| | PIM (dBC) | −142 | −135 | −145 | −140 | −135 | −145 | −140 | −143 |
| | Dk | 3.0 | 2.9 | 2.8 | 3.1 | 3.0 | 2.9 | 3.0 | 3.0 |
| | Df | 0.0030 | 0.0030 | 0.0030 | 0.0035 | 0.0035 | 0.0035 | 0.0035 | 0.0035 |

Test methods of the following performance mentioned in the present disclosure:

Matte side roughness of the copper foil: non-contact laser method.

Element content test in copper foil layer: inductively coupled plasma mass spectrometry.

PIM: Each sample was tested 9 times, each time an intermodulation model and a frequency were selected, and the Summitek Instruments PIM analyzer was used for testing. The maximum value of the 9 test data was recorded, which was the PIM value of the sample. The circuit design length of the intermodulation model was a 12-inch arc and zigzag circuit. The model thickness of samples was 10 mil, 20 mil and 30 mil, corresponding to the line widths of 24 mil, 48 mil and 74 mil respectively; the frequencies were 700 MHz, 1900 MHz and 2600 MHz respectively.

Dk/Df test method: IPC-TM-650 2.5.5.5 standard method was adopted, the frequency was 10 GHz.

Molecular weight test method: National Standard GB T21863-2008-Gel Permeation Chromatography (GPC), tetrahydrofuran was used as an eluent.

Property Analysis:

It can be seen from Examples 1-16 that the dielectric substrate and copper clad laminate, prepared by adopting the iron element weight content of less than 10 ppm, the nickel element weight content of less than 10 ppm, the cobalt element weight content of less than 10 ppm, and the molybdenum element weight content of less than 10 ppm, had less than −158 dBc (700 MHz/2600 MHz) passive intermodulation PIM, which was excellent. The copper clad laminates prepared in Examples 1-16 can meet the high-frequency and high-speed requirements in the electronic information field.

By comparing Comparative Example 1-16 with Example 1-16, it can be seen that the copper foil layer of the prepared dielectric substrate and copper clad laminate had an iron element weight content more than 10 ppm, a nickel element weight content more than 10 ppm, and a cobalt element weight content more than 10 ppm and/or a molybdenum element content of more than 10 ppm, so that the performance of PIM was poor, and cannot meet the requirements of customers for PIM performance.

Obviously, those skilled in the art can make various changes and modifications to the example of the present disclosure without departing from the spirit and scope of the present disclosure. In this way, if these modifications and variations of the present disclosure fall within the scope of the present disclosure according to the claims and equivalent technologies, the present disclosure also intends to include these modifications and variations.

1. A copper clad laminate, comprising:
a dielectric substrate layer, and
a copper foil layer being located on at least one surface of the dielectric substrate layer,
wherein, in the copper foil layer, the weight content of iron element is less than 10 ppm; the weight content of nickel element is less than 10 ppm; the weight content of cobalt element is less than 10 ppm; and the weight content of molybdenum element is less than 10 ppm.

2. The copper clad laminate according to claim 1, wherein the copper clad laminate has a passive intermodulation value of less than −158 dBc at 700 MHz-2600 MHz.

3. The copper clad laminate according to claim 1, wherein the matte side roughness of the copper foil is 0.5-3 μm.

4. The copper clad laminate according to claim 1, wherein the dielectric substrate layer comprising:
a polymer matrix material; and
a filler;
wherein, based on the weight of the dielectric substrate layer, the polymer matrix material is 30 to 70 weight percent; and the filler is 30 to 70 weight percent.

5. The copper clad laminate according to claim 4, wherein the polymer matrix material comprises one or more of a modified or unmodified polybutadiene resin, a modified or unmodified polyisoprene resin, and a modified or unmodified polyarylether resin.

6. The copper clad laminate according to claim 1, wherein the dielectric substrate layer has a dielectric constant less than 3.5 and a dissipation factor less than 0.006 at 10 GHz.

7. The copper clad laminate according to claim 5, wherein the polybutadiene resin is a polybutadiene homopolymer resin or a polybutadiene copolymer resin.

8. The copper clad laminate according to claim 7, wherein the polybutadiene copolymer resin is a polybutadiene-styrene copolymer resin.

9. The copper clad laminate according to claim 5, wherein the modified polybutadiene resin is selected from one or more of a hydroxyl-terminated polybutadiene resin, a methacrylate-terminated polybutadiene resin, and a carboxylated polybutadiene resin.

10. The copper clad laminate according to claim 5, wherein the polyisoprene resin is a polyisoprene homopolymer resin or a polyisoprene copolymer resin.

11. The copper clad laminate according to claim 10, wherein the polyisoprene copolymer resin is a polyisoprene-styrene copolymer resin.

12. The copper clad laminate according to claim 5, wherein the modified polyisoprene resin is a carboxylated polyisoprene resin.

13. The copper clad laminate according to claim 5, wherein the modified polyarylether resin is selected from one or more of carboxyl functionalized polyarylether, methacrylate-terminated polyarylether, and vinyl-terminated polyarylether.

14. The copper clad laminate according to claim 5, wherein the polymer matrix material further comprises selected from one or more of co-curable polymers other than a polybutadiene resin, a polyisoprene resin and a polyarylether resin, a free radical curing monomer, an elastomer block copolymer, an initiators, a flame retardant, a viscosity modifier and a solvent.

15. The copper clad laminate according to claim 1, wherein the dielectric substrate layer comprises a reinforcing material or no reinforcing material.

16. The copper clad laminate according to claim 1, further comprising a bonding layer and/or a resin film layer located between the copper foil and the dielectric substrate layer.

17. A printed circuit board comprising the copper clad laminate according to claim 1.

18. The copper clad laminate according to claim 2, further comprising a bonding layer and/or a resin film layer located between the copper foil and the dielectric substrate layer.

19. The copper clad laminate according to claim 3, further comprising a bonding layer and/or a resin film layer located between the copper foil and the dielectric substrate layer.

20. The copper clad laminate according to claim 4, further comprising a bonding layer and/or a resin film layer located between the copper foil and the dielectric substrate layer.
